(19) United States
(12) Patent Application Publication
(10) Pub. No.: US 2009/0163049 A1
(43) Pub. Date: Jun. 25, 2009

(54) ELECTRONIC MODULE

(75) Inventors: Yuji Ono, Fukaya-shi (JP); Mikine Fujihara, Fukaya-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/204,711

(22) Filed: Sep. 4, 2008

(30) Foreign Application Priority Data
Dec. 21, 2007 (JP) 2007-329749

(51) Int. Cl. H05K 1/00

(52) U.S. Cl. 439/66

(57) ABSTRACT

An electronic module includes: a first circuit board and a second circuit board; and a conductive connector for electrically connecting a first conductive pattern of the first circuit board with a second conductive pattern of the second circuit board, wherein at least one of the first circuit board and the second circuit board is connected with the conductive connector through intrusion thereof.

### CROSS-REFERENCE TO RELATED APPLICATIONS

This application is based upon and claims the benefit of priority from the prior Japanese Patent Application No. 2007-329749, filed on Dec. 21, 2007; the entire contents of which are incorporated herein by reference.

### BACKGROUND OF THE INVENTION

1. Field of the Invention

The present invention relates to an electronic module usable for a mobile terminal, a personal computer, an electronic tuner with a built-in PC card and a high frequency electronic component.

2. Description of the Related Art

In order to electrically and mechanically connect two or more circuit boards, conventionally, a plug is formed on one of the circuit boards and a receptacle is formed on another of the circuit boards so that the plug is intruded into the receptacle. The plug has connecting terminals on the outer sides thereof and the receptacle also has connecting terminals on the inner sides thereof. According to the intrusion of the plug into the receptacle, the circuit boards can be mechanically connected with one another and also electrically connected with one another through the connections between the connecting terminals of the plug and the connecting terminals of the receptacle (refer to Reference 1).

Recently, on the other hand, it is required that an electronic component such as a mobile terminal and an electronic tuner is required to be enhanced and diversified in inherent function, and to be downsized and thinned. In this point of view, it is also required that the electronic module relating to the electronic component is downsized and thinned.

In Reference 1, however, since the sizes of the plug and the receptacle are set relatively large, the functional areas (effective areas) of the circuit boards for the corresponding conductive patterns to be formed may be narrowed when the plug and the receptacle are formed on the circuit boards. In Reference 1, moreover, since it is required to form, on the circuit boards, the connecting areas for the plug and the receptacle to be formed in addition to the effective areas so that the total sizes of the circuit boards may result in being enlarged, which is contrary to the above-described requirement for downsizing and thinning the circuit boards.

[Reference 1] JP-B2 2908325 (Patent Publication)

### BRIEF SUMMARY OF THE INVENTION

It is an object of the present invention to provide an electronic module configured such that two or more circuit boards are electrically and mechanically connected with one another under the condition that the sizes of the circuit boards are not enlarged.

In order to achieve the above object, an aspect of the present invention relates to an electronic module, including: a first circuit board and a second circuit board; and a conductive connector for electrically connecting a first conductive pattern of the first circuit board with a second conductive pattern of the second circuit board, wherein at least one of the first circuit board and the second circuit board is connected with the conductive connector through intrusion thereof.

According to the aspects of the present invention can be provided an electronic module configured such that two or more circuit boards are electrically and mechanically connected with one another under the condition that the sizes of the circuit boards are not enlarged.

### BRIEF DESCRIPTION OF THE SEVERAL VIEWS OF THE DRAWINGS

FIG. 1 is a structural view showing a conductive connector to be employed in an electronic module according to a first embodiment.

FIG. 2 is a side view showing the conductive connector to be employed in the electronic module according to the first embodiment.

FIG. 3 is a side view showing the electronic module according to the first embodiment.

FIG. 4 is a front view showing the electronic module according to the first embodiment, taken on line “I-I” and viewed from the direction designated by “A”.

FIG. 5 is a structural view showing a conductive connector to be employed in an electronic module according to a second embodiment.

FIG. 6 is a side view showing the conductive connector to be employed in the electronic module according to the second embodiment.

FIG. 7 is a side view showing the electronic module according to the second embodiment.

FIG. 8 is a front view showing the electronic module according to the first embodiment, taken on line “I-I” and viewed from the direction designated by “A”.

FIG. 9 is a side view showing the structure of a conductive connector to be employed in an electronic module according to a third embodiment.

FIG. 10 is a front view showing the structure of the conductive connector to be employed in the electronic module according to the third embodiment.

FIG. 11 is an explanatory view showing the structure of an electronic module according to a forth embodiment.

### DETAILED DESCRIPTION OF THE INVENTION

Hereinafter, the present invention will be described in detail with reference to the drawings.

### First Embodiment

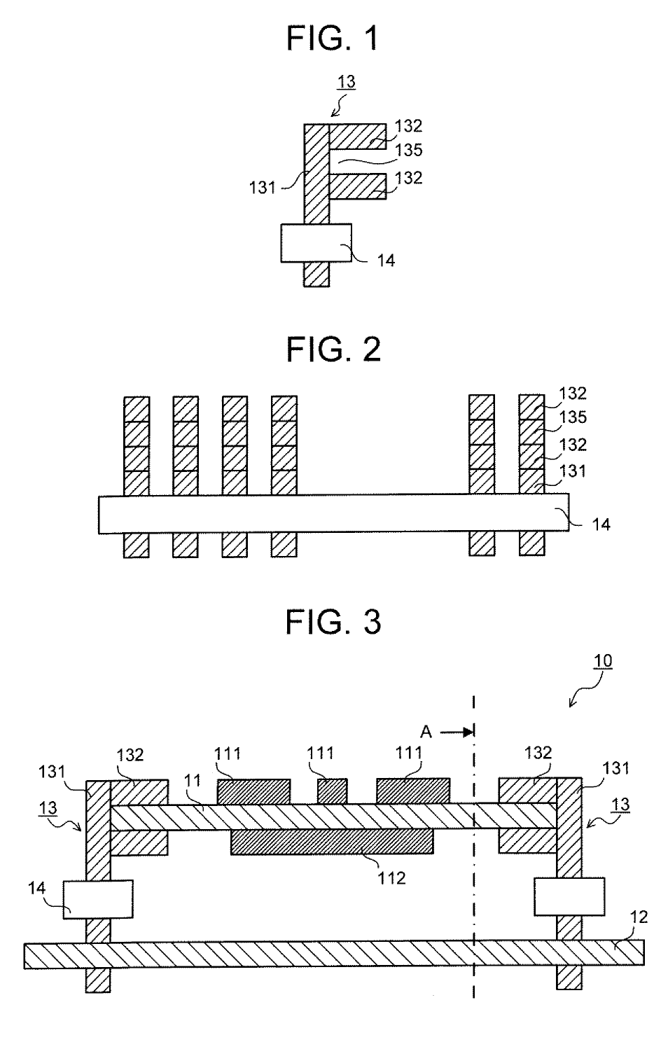

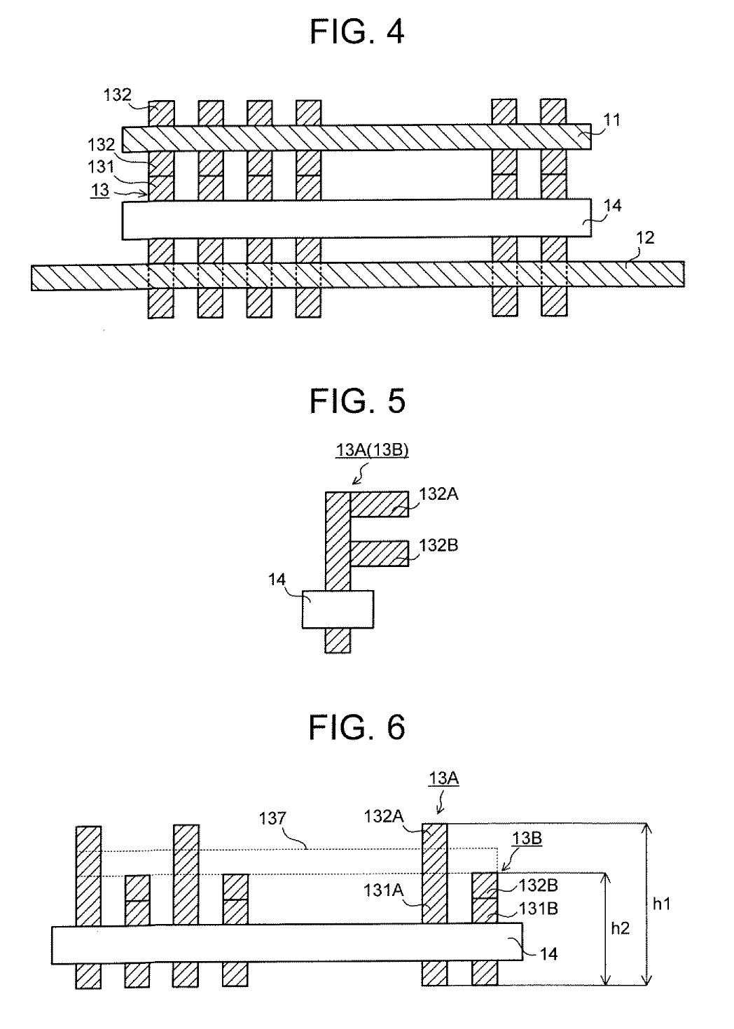

FIGS. 1 to 4 are explanatory views for the electronic module in this embodiment. FIG. 1 is a structural view showing a conductive connector to be employed in an electronic module in this embodiment, and FIG. 2 is a side view showing the conductive connector in this embodiment. FIG. 3 is a side view showing the electronic module in this embodiment, and FIG. 4 is a front view showing the electronic module, taken on line “I-I” and viewed from the direction designated by “A”.

As shown in FIGS. 1 and 2, the conductive connector in this embodiment includes a plurality of conductive connecting pieces 13 which are fixed with a mold 14 and arranged at certain intervals. Each conductive connecting piece 13 includes a lead portion 131 elongated vertically and a gripping portion 132 which is provided at the side of the top of the lead portion 131 and protruded in the direction perpendicular to the long direction of the lead portion 131.

The gripping portion 132 is configured as a pair of gripping portions 132 which are separated vertically from one another by a predetermined distance. The lengths of the adjacent conductive connecting pieces 13 are set equal to one another so that the positions of the gripping portions 132 in between adjacent ones of the conductive connecting pieces 13 are also set equal to one another. As a result, a common space 135 is formed through the gripping portions 132 in between the adjacent ones of the conductive connecting pieces 13.

Then, the electronic module in this embodiment will be described. As shown in FIGS. 3 and 4, the electronic module 10 in this embodiment includes a first circuit board 11 and a second circuit board 12. The first circuit board 11 includes electronic components 111 and 112 exhibiting inherent function of the electronic module 10 on the main surface and the rear surface thereof and conductive patterns (circuit patterns, not shown) corresponding to the electronic components 111 and 112. The second circuit board 12 includes conductive patterns such as a control signal circuit for transmitting a control signal to the first circuit board 11 and an electronic power supply circuit (not shown) for supplying a power supply voltage to the first circuit board 11.

The first circuit board 11 in this embodiment is exemplified and thus, may be configured as occasion demands. The second circuit board 12 functions as an external circuit board for the first circuit board 11 and thus, may include an image processing circuit and the like in addition to the electronic power supply circuit.

As shown in FIGS. 3 and 4, the first circuit board 11 and the second circuit board 12 are electrically and mechanically connected with one another by the conductive connector shown in FIGS. 1 and 2. Concretely, the ends of the conductive connecting pieces 13 opposite to the tops thereof with the gripping portions 132 are intruded and fixed into the through holes (not shown) of the second circuit board 12 while the first circuit board 11 is gripped in the common space 135 formed by the gripping portions 132 in between the adjacent conductive connecting pieces 13. In this point of view, the first circuit board 11 is mechanically connected with the second circuit board 12.

Since the conductive connecting pieces 13 (lead portions 131) are intruded into the through holes of the second circuit board 12 so as to be electrically contacted with a conductive pattern (not shown) formed on the second circuit board 12 while the first circuit board 11 is gripped so that the gripping portions 132 can be electrically contacted with a conductive pattern (not shown) on the first circuit board 11, the first circuit board 11 is also electrically connected with the second circuit board 12.

As apparent from FIGS. 3 and 4, the lead portion 131 of each conductive connecting piece 13 is disposed along the direction parallel to the stacking direction of the first circuit board 11 and the second circuit board 12.

In this way, in the electronic module 10 in this embodiment, the first circuit board 11 is electrically and mechanically connected with the second circuit board 12 with the conductive connectors, concretely, the conductive connecting pieces 13. Since the size of the conductive connecting piece 13 (lead portion 131 and the gripping portions 132) is much smaller than the size of the plug or the receptacle shown in Reference 1, and then, set almost equal to the size of the connecting terminal shown in Reference 1, the functional areas (effective areas) such as forming the respective conductive patterns of the first circuit board 11 and the second circuit board 12 can not be narrowed.

Moreover, since the size of the conductive connecting piece 13 is set small sufficiently, it is not required to form other connecting areas such as forming the plug, the receptacle and the like on the first circuit board 11 and the second circuit board 12 in addition to the functional areas (effective areas) thereon.

Concretely, the first circuit board 11 is gripped at the edges thereof with the gripping portions 132 of the conductive connecting pieces 13, and electrically and mechanically connected with the second circuit board 12 through the gripping. Since the sizes of the gripping portions 132 are smaller than the conventional plug and the like, the functional area of the first circuit board 11 is not affected by the gripping with the gripping portions 132. Apparently, no connecting area is required in addition to the functional area. Since the first circuit board 11 is gripped with the gripping portions 132 so that the conductive pattern of the first circuit board 11 is electrically contacted with the gripping portions 132, the connecting area may not disturb the electrical connection between the conductive pattern and the gripping portions 132.

In the electrical and mechanical connection between the first circuit board 11 and the second circuit board 12, since it is only required for the second circuit board 12 to form the through holes therein for intruding the conductive connectors (conductive connecting pieces 13), the functional area of the second circuit board can not be narrowed. Moreover, since the sizes of the through holes are small sufficiently, no connecting area is required in addition to the functional area on the second circuit board 12. The through holes may be formed in the spare area of the functional area in the second circuit board 12.

Therefore, the first circuit board 11 and the second circuit board 12 can be electrically and mechanically connected with one another tightly by the conductive connectors (conductive connecting pieces 13) under the condition that the sizes of the first circuit board 11 and the second circuit board 12 are not enlarged. The connection between the first circuit board 11 and the second circuit board 12 can satisfy the requirement of downsizing the electronic module.

In the case that the gripping portions 132 of the conductive connecting pieces 13 are soldered with the first circuit board 11, since the soldering process is carried out under the condition that the first circuit board 11 is gripped with the gripping portions 132, the soldering process can be carried out surely with pinpoint under no position shift. Moreover, since the soldering process is carried out for the first circuit board 11 via the gripping portions 132, the soldering strength can be enhanced.

### Second Embodiment

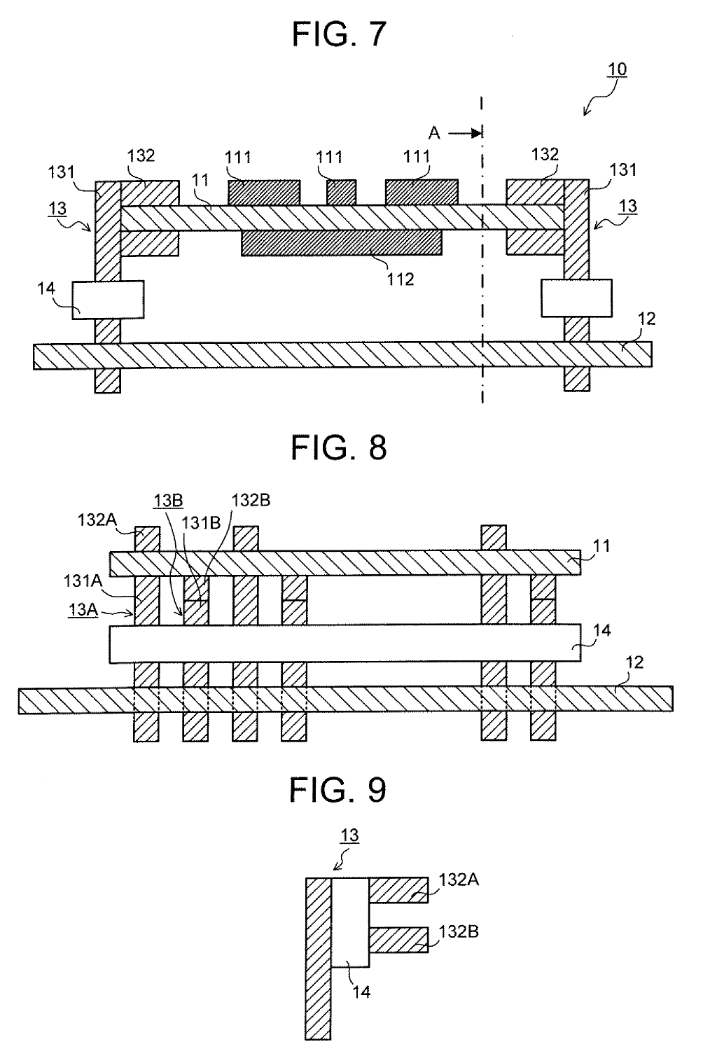

FIGS. 5 to 8 are explanatory views for the electronic module in this embodiment. FIG. 5 is a structural view showing a conductive connector to be employed in the electronic module in this embodiment, and FIG. 6 is a side view showing the conductive connector. FIG. 7 is a side view showing the electronic module in this embodiment, and FIG. 8 is a front view showing the electronic module, taken on line “I-I” and viewed from the direction designated by “A”. Like or corresponding components are designated by the same reference numerals. Then, similar components and/or structures may be omitted or simplified in explanation.

As shown in FIGS. 5 and 6, the conductive connector in this embodiment includes a plurality of conductive connecting pieces 13A and 13B which are fixed with the mold 14 and arranged alternately at certain intervals. Each conductive connecting piece 13A and each conductive connecting piece 13B respectively include a lead portion 131A and a lead portion 131B which are elongated vertically, and a gripping portion 132A and a gripping portion 132B which are respectively provided at the sides of the tops of the lead portions 131A and 131B and protruded in the direction perpendicular to the long direction of the lead portions 131A and 131B.

Each conductive connecting piece 13A has a first length “h1” and each conductive connecting piece 13B has a second length “h2”. The first length “h1” is set larger than the second length “h2” so that the gripping portion 132A of the conductive connecting piece 13A can be shifted from the gripping portion 132B of the conductive connecting piece 13B. In this case, a common space 137 is formed through the gripping portions 132A and the gripping portions 132B in between the conductive connecting pieces 13A and the conductive connecting pieces 13B which are alternately disposed.

Then, the electronic module in this embodiment will be described. As shown in FIGS. 7 and 8, the electronic module 10 in this embodiment includes a first circuit board 11 and a second circuit board 12. The first circuit board 11 includes electronic components 111 and 112 exhibiting inherent function of the electronic module 10 on the main surface and the rear surface thereof and conductive patterns (circuit patterns, not shown) corresponding to the electronic components 111 and 112. The second circuit board 12 includes conductive patterns such as a control signal circuit for transmitting a control signal to the first circuit board 11 and an electronic power supply circuit (not shown) for supplying a power supply voltage to the first circuit board 11.

As shown in FIGS. 7 and 8, the first circuit board 11 and the second circuit board 12 are electrically and mechanically connected with one another with the conductive connector shown in FIGS. 3 and 4. Concretely, the ends of the conductive connecting pieces 13A and the 13B opposite to the tops thereof with the respective gripping portions 132A and 132B are intruded and fixed into the through holes (not shown) of the second circuit board 12 while the first circuit board 11 is gripped in the common space 137 formed by the gripping portions 132A and 132B of the conductive connecting pieces 13A and 13B (lead portions 131A and 131B) which are alternately arranged. In this point of view, the first circuit board 11 is mechanically connected with the second circuit board 12.

Since the conductive connecting pieces 13A and 13B (lead portions 131A and 131B) are intruded into the through holes of the second circuit board 12 so as to be electrically contacted with a conductive pattern (not shown) formed on the second circuit board 12 while the first circuit board 11 is gripped so that the gripping portions 132A and 132B can be electrically contacted with a conductive pattern (not shown) on the first circuit board 11, the first circuit board 11 is also electrically connected with the second circuit board 12.

As apparent from FIGS. 7 and 8, the lead portion 131A of each conductive connecting piece 13A and the lead portion 131B of each conductive connecting piece 13B are disposed along the direction parallel to the stacking direction of the first circuit board 11 and the second circuit board 12.

In this way, the second embodiment can exhibit the same function/effect as the first embodiment. Moreover, the second embodiment can exhibit the additional function/effect.

Since the length “h1” of the lead portions 131A of the conductive connecting pieces 13A is set different from the length “h2” of the lead portions 131B of the conductive connecting pieces 13B (herein, h1>h2), the top ends of the conductive connecting pieces 13A are protruded from the top ends of the conductive connecting pieces 13B so that the common space 137 is formed between the top ends of the conductive connecting pieces 13A and the top ends of the conductive connecting pieces 13B. Therefore, the first circuit board 11 can be soldered with the gripping portions 132A and 132B surely and easily using the common space with pinpoint.

In view of the soldering process, since the electronic module 10 in this embodiment is configured as the one in the first embodiment, the electronic module 10 can exhibit the same function/effect in the same manner as the first embodiment.

In addition, the soldering process can be carried out tightly originated from the working easiness and the accuracy thereof and from the soldering between the first circuit board 11 and the gripping portions 132A, 132B.

### Third Embodiment

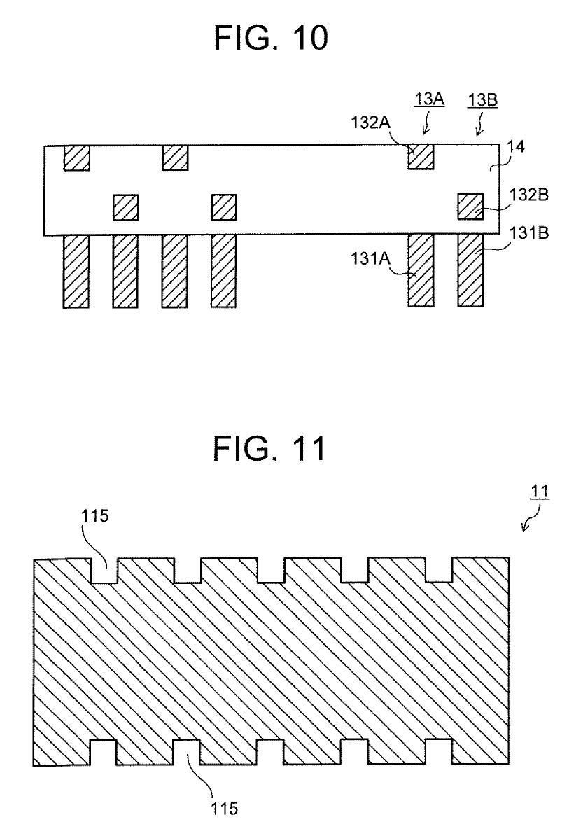

FIG. 9 is a side view showing the structure of a conductive connector to be employed in an electronic module in this embodiment, and FIG. 10 is a front view showing the structure of the conductive connector. Like or corresponding components are designated by the same reference numerals.

The third embodiment corresponds to a modified embodiment of the second embodiment. In this embodiment, the mold 14 is disposed between the lead portions 131A, 131B and the gripping portions 132A, 132B in the conductive connecting pieces 13A and 13B while not fixing the conductive connecting pieces 13A and 13B. Since the gripping portions 132A and 132B are penetrated through the mold 14 to be connected with the corresponding lead portions 131A and 1311B, the electric conduction in the conductive connecting pieces 13A and 13B are not deteriorated at all.

Therefore, when the first circuit board 11 is electrically and mechanically connected with the second circuit board 12 with the conductive connecting portions 13A and 13B so that the first circuit board 11 is gripped with the gripping portions 132A and 132B, the electric module 10 in this embodiment is configured as the one in the second embodiment except that the mold 14 is disposed between the first circuit board 11 and the lead portions 131A, 131B.

In this point of view, the third embodiment can exhibit the same function/effect as the second embodiment. Concretely, the first circuit board 11 can be electrically and mechanically connected with the second circuit board 12 under no enlargement in size and the soldering process of the first circuit board 11 for the gripping portions 132A, 132B can be carried out surely and tightly.

### Fourth Embodiment

FIG. 11 is an explanatory view showing the structure of an electronic module in this embodiment. Concretely, FIG. 11 shows the top surface of the first circuit board 11. For simplification, the electronic components and the like will be omitted.

In this embodiment, a plurality of depressed portions 115 are formed at certain intervals at the peripheral edge, concretely, the top peripheral edge and the bottom peripheral edge of the first circuit board 11. In this case, even though the conductive connecting pieces 13 (13A or 13B) in the first embodiment through the third embodiment have no gripping portion, respectively, the first circuit board 11 can be mechanically held by the conductive connecting pieces 13 (13A and 13B) and can be electrically contacted with the conductive connecting pieces 13 (13A and 13B) by intruding the lead portions 131 of the conductive connecting pieces 13 into the depressed portions 115, respectively.

Therefore, when the ends of the conductive connecting pieces 13 (13A and 13B) opposite to the tops thereof with the gripping portions 132 (132A and 132B) are intruded and fixed into the through holes (not shown) of the second circuit board 12 in the same manner as the first embodiment through the third embodiment, the first circuit board 11 is electrically and mechanically connected with the second circuit board 12 with the conductive connecting pieces with no gripping portion.

Although the present invention was described in detail with reference to the above examples, this invention is not limited to the above disclosure and every kind of variation and modification may be made without departing from the scope of the present invention. For example, the second circuit board 12 may be gripped with the conductive connector in addition to or instead of the first circuit board 11.

What is claimed is:

1. An electronic module, comprising:
a first circuit board and a second circuit board; and
a conductive connector for electrically connecting a first conductive pattern of said first circuit board with a second conductive pattern of said second circuit board,
wherein at least one of said first circuit board and said second circuit board is connected with said conductive connector through intrusion thereof.

2. The electronic module as set forth in claim 1,
wherein said at least one of said first circuit board and said second circuit board is gripped with said conductive connector.

3. The electronic module as set forth in claim 2,
wherein said conductive connector includes a lead portion elongated vertically along a stacking direction of said first circuit board and said second circuit board and a gripping portion protruded in a direction perpendicular to a long direction of said lead portion,
wherein said at least one of said first circuit board and said second circuit board is gripped with said gripping portion.

4. The electronic module as set forth in claim 3,
wherein said conductive connector includes a plurality of conductive connecting pieces so that each conductive connecting piece includes said lead portion and said gripping portion.

5. The electronic module as set forth in claim 4,
wherein a length of one of said conductive connecting pieces is set different from a length of another of said conductive connecting pieces adjacent to said one thereof so that a position of said gripping portion in said one of said conductive connecting pieces is different from a position of said gripping portion in said another thereof.

6. The electronic module as set forth in claim 1,
wherein a depressed portion is formed at a peripheral edge of said at least one of said first circuit board and said second circuit board so that said at least one thereof is connected with said conductive connector by intruding said conductive connector into said depressed portion thereof.

7. The electronic module as set forth in claim 1,
wherein a through hole is formed at the other of said first circuit board and said second circuit board,
wherein said the other of said first conductive circuit and said second circuit boards is connected with said conductive connector by intruding said conductive connector into said through hole thereof.

8. The electronic module as set forth in claim 2,
wherein said at least one of said first circuit board and said second circuit board is partially soldered with said conductive connector.

9. The electronic module as set forth in claim 3,
wherein said at least one of said first circuit board and said second circuit board is soldered with said gripping portion of said conductive connector.
